(19) United States
(12) Patent Application Publication
(10) Pub. No.: US 2014/0273329 A1
(43) Pub. Date: Sep. 18, 2014

(54) SOLAR CELL LASER SCRIBING METHODS

(71) Applicant: TSMC SOLAR LTD., Taichung City (TW)

(72) Inventors: Hsuan-Sheng YANG, Taipei City (TW); Kwang-Ming LIN, Hsin-Chu City (TW); Yi-Feng HUANG, kaohsiung City (TW); Li-Wei CHANG, Taipei City (TW); Chia-Hung TSAI, Kaohsiung City (TW)

(73) Assignee: TSMC SOLAR LTD., Taichung City (TW)

(21) Appl. No.: 13/798,555

(22) Filed: Mar. 13, 2013

(51) Int. Cl. H01L 31/042

(52) U.S. Cl. CPC H01L 31/042
USPC 438/68

(57) ABSTRACT

A multi-step scribing operation is provided for forming scribe lines in solar panels to form multiple interconnected cells on a solar panel substrate. The multi-step scribing operation includes at least one step utilizing a nanosecond laser cutting operation. The nanosecond laser cutting operation is followed by a mechanical cutting operation or a subsequent nanosecond laser cutting operation. In some embodiments, the multi-step scribing operation produces a two-tiered scribe line profile and the method prevents local shunting and minimizes active area loss on the solar panel.

### TECHNICAL FIELD

The disclosure relates most generally to solar cell devices and more particularly to methods for forming scribe lines in solar panels used to form solar cell devices.

### BACKGROUND

Solar cells are photovoltaic components for direct generation of electrical current from sunlight. Due to the growing demand for clean sources of energy, the manufacture of solar cells has expanded dramatically in recent years and continues to expand. All solar cells include an absorber layer and one common absorber layer is CIGS, copper indium gallium selenide. Transparent conductive oxide, TCO, films are commonly disposed over the absorber layers in solar cells. TCO films are popular materials due to their versatility as transparent coatings and also as electrodes and function as top contacts for the solar cells.

Solar cells are often manufactured in the form of thin film solar panels. Thin film solar panels are gaining in popularity because they are less expensive to manufacture and are formed on very large substrates. These very large substrates that serve as one solar cell can have poor conversion efficiencies. Thus, multiple interconnected or separated solar cells are created from the large solar panels by separating the solar panel into efficiently sized solar cells. The solar cells are separated by scribe lines in a scribing process. Scribe lines are formed by identifying scribe line regions and removing materials from the scribe lines to separate the cells.

Improvements in scribing methods for solar panels continue to be sought.

### BRIEF DESCRIPTION OF THE DRAWING

The present disclosure is best understood from the following detailed description when read in conjunction with the accompanying drawing. It is emphasized that, according to common practice, the various features of the drawing are not necessarily to scale. On the contrary, the dimensions of the various features may be arbitrarily expanded or reduced for clarity. Like numerals denote like features throughout the specification and drawing.

FIGS. 1A-1C are cross-sectional views showing the formation of a scribe line according to an embodiment of the disclosure;

FIGS. 2A-2E are cross-sectional views showing a method for forming a scribe line in a solar panel according to an embodiment of the disclosure;

FIG. 3 shows various beam profiles of a nanosecond laser used according to methods of the disclosure; and

FIGS. 4A-4E are cross-sectional views showing another method for forming a scribe line in a solar panel according to another embodiment of the disclosure.

### DETAILED DESCRIPTION

Methods for forming scribe lines in solar panels are provided. The methods are for scribing photovoltaic structures to form monolithically integrated photovoltaic modules. Scribe lines separate the solar panels into individual solar cells and the individual solar cells are arranged in arrays in some embodiments. In other embodiments, the solar panels are scribed to create multiple solar cells that are interconnected in series. In some embodiments, groups of serially connected solar cells are connected in parallel.

Current methods for forming the scribe lines include mechanical patterning. In mechanical patterning, a stylus is used to mechanically etch micro-channels into the solar panels to form individual solar cells typically in the form of an array. Commercially used mechanical scribing methods may not create high-quality, highly defined channels and may result in film cracking which reduces the active area from which electricity is generated. The film cracking generates contaminants and often results in a decreased conversion efficiency of the solar cell.

Some laser patterning methods have also been used to form scribe lines. Such methods utilize pico-second lasers which are expensive and may undesirably create shunting between the TCO or other top electrode, and the back electrode. Current laser scribing techniques also cause thermal melting and splattering of conductive material such as TCO which can cause undesirable shorting between adjacent solar cells.

The method of the disclosure utilizes a nanosecond laser, i.e. a laser with a pulse frequency in the nanosecond range and the disclosure provides for a multiple step process for forming scribe lines on solar panels. At least one of the steps includes the use of a nanosecond laser. Nanosecond lasers are relatively inexpensive to own and operate (compared to picosecond lasers) and the methods of the disclosure provide for scribing the layers of the solar panel with virtually no cracking or particle production, eliminating common causes of cell shunting and maximizing conversion efficiency. Various embodiments of the disclosure include methods in which a first nanosecond laser cutting operation is followed by a mechanical scribing operation and other embodiments of the disclosure are methods in which a first nanosecond laser cutting operation is followed by a second nanosecond laser cutting operation. In some embodiments, the multi-step process for scribing solar panels involves more than two steps.

FIG. 1A is a cross-sectional view showing portions of a film stack used in solar panels according to one embodiment. Absorber layer 2 is a GIGS (Cu(In, Ga)Se₂) absorber layer in one embodiment but other suitable absorber layers are used in other embodiments. Cadmium telluride (CdTe), gallium arsenide (GaAs) or amorphous silicon (A-Si) are used as absorber layer 2 in other embodiments. Absorber layer 2 is the layer in which photons from sunlight become converted to electrical current. TCO layer 4 is disposed over absorber layer 2 and serves as, and is often referred to as, the top contact of the solar cell. The top contact is a transparent and conductive layer for current collection and light enhancement. TCO layer 4 is ITO, indium tin oxide, in one embodiment and TCO layer 4 is one of ZnO, AZO, BZO, GZO or indium-doped cadmium oxide in other embodiments. TCO layer 4 and absorber layer 2 are each formed to various suitable thicknesses and the individual and total thicknesses vary in various embodiments. In some embodiments, TCO layer 4 is formed directly on absorber layer 2 and in other embodiments, a buffer layer such as a CdS buffer layer or a ZnS buffer layer is interposed between TCO layer 4 and absorber layer 2 although the disclosure will be described and illustrated hereinafter with respect to an embodiment in which TCO layer 4 is formed directly on absorber layer 2. Absorber layer 2 is disposed over back electrode layer 6. In one embodiment, back electrode layer 6 is a molybdenum, Mo layer. In other embodiments, back electrode layer 6 is formed of other suitable materials used to establish ohmic contact between the solar panel and other components.

FIG. 1B shows the structure of 1A after initial opening 10 is formed in the structure. In the illustrated embodiment, initial opening 10 extends completely through TCO layer 4 and into absorber layer 2 but different results are achieved in other embodiments. The disclosure provides a multiple-step method for producing scribe lines in solar panels and the structure shown in FIG. 1B with initial opening 10 is the opening formed after the first of multiple steps of scribe line formation according to various embodiments. FIG. 1C shows a structure after the second of multiple step operations have been used to form a scribe line. Further, FIG. 1C shows the structure of FIG. 1B after a second scribe line formation operation has been carried out. Two-tiered opening 12 includes lower portion 14 and upper portion 16 and two-tiered opening 12 extends completely through TCO layer 4 and absorber layer 2 and represents one configuration of a scribe line profile formed according to the disclosure. Upper portion 16 includes width 20 which is greater than width 22 of lower portion 14. FIGS. 1A-1C are shown in cross-sectional view and it should be understood that initial opening 10 and two-tiered opening 12 that forms the scribe line extend along the surface of the solar panel in areas identified as scribe line regions.

Various methods for forming the structure in 1C are used according to various embodiments of the disclosure as will be described below.

FIG. 2A shows the structure also shown in FIG. 1A. Absorber layer 2 and TCO layer 4 represent a stack of layers 26. FIG. 2B shows a first step of a multi-step scribe line formation operation and shows a cutting step using shaped laser beam 24. The scribe lines are first identified and the laser scribing and mechanical scribing methods described herein, involve the laser or mechanical stylus travelling along the scribe lines according the methods described herein.

Shaped laser beam 24 is a nanosecond laser beam and performs a cutting operation on the structure shown in FIG. 2A to produce the structure shown in FIG. 2C. In FIG. 2B, shaped laser beam 24 extends through TCO layer 4 and begins to cut into top portion of absorber layer 2. In other embodiments, shaped laser beam 24 does not extend completely through TCO layer 4, and in still other embodiments, shaped laser beam 24 extends further down into absorber layer 2. Absorber layer 2 and TCO layer 4 form stack of layers 26 with an overall thickness 30 and in the first step of the multi-step scribe line formation operation, only a portion of overall thickness 30 is removed. In other embodiments, stack of layers 26 includes additional layers such as one or more buffer layers.

Still referring to FIG. 2C, initial opening 10 is formed within stack of layers 26. The depth of initial opening 10 may vary, and will depend upon overall thickness 30 and the thickness of TCO layer 4, which varies in various embodiments. In some embodiments, initial opening 10 extends into absorber layer 2 by depth 32 which ranges from less than 100 nm to 2 um in various embodiments. Although the disclosure is described with respect to the illustrated embodiment in which TCO layer 4 is formed directly on absorber layer 2, in other embodiments, a buffer layer is interposed between absorber layer 2 and TCO layer 4 and is removed in the first scribing operation along with TCO layer 4 when initial opening 10 is created.

FIG. 2D illustrates a second step of a multi-step scribe line formation operation according to an embodiment in which a nanosecond laser cutting operation is used in both the first and second steps. FIG. 2D shows shaped laser beam 34 cutting downwardly into absorber layer 2 and through the bottom of initial opening 10. The second, nanosecond laser cutting operation utilizing shaped laser beam 34, produces the two-tiered opening shown in FIG. 2E. According to one embodiment, the first nanosecond laser cutting operation shown in FIG. 2B removes TCO layer 4 but not absorber layer 2 from the first scribe line region and the second nanosecond cutting operation shown in FIG. 2D removes absorber layer 2 from the scribe line region. The second, nanosecond laser cutting operation clears any residual portions of TCO layer 4 that may remain after the initial nanosecond laser cutting operation and prevents localized shunting between TCO layer 4 and back electrode layer 6.

FIG. 2E shows the structure also shown and described in FIG. 1C. Two-tiered opening 12 includes lower portion 14 and upper portion 16 and two-tiered opening 12 extends completely through TCO layer 4 and absorber layer 2. Upper portion 16 includes width 20 which is greater than width 22 of lower portion 14. In one embodiment, width 20 lies within the range of about 50-300 um in width, but other widths are used in other embodiments. Width 22 of lower portion 14 produced by the second nanosecond laser cutting operation lies within a range between about 50-200 um in various embodiments and in one embodiment width 22 lies within a range of about 50-100 um. In one embodiment, width 22 of lower portion 14 is about 10-30 um smaller than width 20 of upper portion 16. The numerical values are provided by way of example only and in other embodiments, other scribe line widths are produced.

The two-tiered profile of the scribe line opening 12 shown in FIG. 2E, is exemplary only and the scribe line formed according to the methods of the disclosure has other shapes and configurations in other embodiments. In some embodiments, the scribe line has a rectangular cross-sectional profile.

The nanosecond laser cutting operations utilize shaped laser beam 24 or shaped laser beam 34. In one embodiment, the shaped laser beam includes a radiation wavelength that varies from about 200 to 1100 nm in various embodiments, and in one embodiment, the laser operates with a radiation wavelength within the range of about 500-550 nm. In some embodiments, the nanosecond laser utilizes a beam with radiation having a wavelength within the range of about 200-300 nm. In another embodiment, the nanosecond laser beam is a visible light beam with a wavelength within the range of about 400-700 nm, and in another embodiment, the nanosecond laser utilizes a beam of radiation with a wavelength within the range of about 1000-1200 nm. The nanosecond laser operates using a pulse that ranges from about 0.1 ns (nanoseconds) to about 100 ns in various embodiments. In one embodiment, the nanosecond laser utilizes a pulse rate of about 0.8 to 30 ns. Various pulse energies are used for the shaped laser beam in various embodiments. In one embodiment, the pulse energy ranges from about 3 uJ (microJoules) to about 20 uJ, but other energies are used in other embodiments.

Shaped laser beams 24, 34 are shaped using various suitable means to shape the energy profiles of a laser beam across a laser beam spot.

FIG. 3 shows various laser beam energy profiles 50 and laser beam energy profile 52. In particular, FIG. 3 shows four profiles of shaped laser beams according to various embodiments of the disclosure, but various other shaped beam profiles are used in other embodiments. FIG. 3 shows three embodiments of smooth, parabolic energy profiles 50 of a shaped laser as used in various embodiments of the disclosure. The parabolic energy profiles 50 of the shaped laser beam include various energy distributions and include a more widened energy profile, an intermediate parabolic energy profile and a more flattened energy distribution from left to right, in FIG. 3. In one embodiment, the laser beam energy profile is a step energy profile 52 as shown in FIG. 3. The different laser beam energy profiles of FIG. 3 demonstrate various embodiments in which different energy distributions across the laser beam are used. A “narrower” laser beam energy profile such as in the laser beam energy profile at the far left-hand side of FIG. 3 is used in some embodiments in which a sharper side wall with less thermal impact can be made for a scribe line. In some embodiments, the shape of the shaped laser beam, i.e. the laser beam energy profile, is dynamically varied during the laser scribing operation.

According to the embodiment in which two nanosecond laser cutting operations are used, the beam profile and other laser beam parameters and settings are the same in each of the nanosecond laser cutting operations in some embodiments, the beam profile and other laser beam parameters and settings differ in the two nanosecond laser cutting operations.

FIGS. 4A-4E show another multi-step scribe line formation operation according to the disclosure. FIGS. 4A-4C are identical to FIGS. 2A-2C and illustrate a first step of a multi-step scribing operation sequence in which shaped laser beam 24 cuts through TCO layer 4 and slightly into absorber layer 2 to form initial opening 10.

FIG. 4D shows a second, mechanical cutting step according to another embodiment of the disclosure. According to the embodiment illustrated in FIGS. 4A-4E, after a first nanosecond laser cutting operation takes place in FIG. 4B, a second mechanical cutting operation takes place as illustrated in FIG. 4D and utilizing mechanical stylus 58. Mechanical stylus 58 is formed of various suitable metals in various embodiments and includes various different rigid and non-deformable shapes. Mechanical stylus 58 is various sizes in various embodiments. Suitable pressure is applied to mechanical stylus 58 as mechanical stylus 58 translates along the scribe line direction to mechanically remove portions of absorber layer 2 down to back electrode layer 6. Various pressures and various speeds are used in various embodiments and mechanical stylus 58 represents a component of various mechanical scribing tools in various embodiments. The second, mechanical cutting operation prevents localized shunting between TCO layer 4 and back electrode layer 6, as the mechanical cutting operation removes any remnants of TCO layer 4 that may remain after the initial nanosecond laser cutting operation.

FIG. 4E illustrates the structure also shown in FIGS. 1C and 2E and formed according to the sequence of processing operations illustrated in FIGS. 4A-4D.

The disclosure is not limited to the two method embodiments described herein. In other embodiments, the multi-step scribe line formation method includes additional steps. In one embodiment, two nanosecond laser scribing operations are used in conjunction with a mechanical scribing operation. The methods of the disclosure produce solar cells with minimized active area loss which increases conversion efficiency and are formed using a low-cost nanosecond laser that prevents local shunting.

According to one aspect, a method for patterning a solar cell is provided. The method comprises providing a solar panel with at least an absorber layer and a transparent conductive oxide (TCO) layer over the absorber layer and creating scribe lines in the solar panel using a multiple step process in which at least a first step of the multiple steps is a nanosecond laser cutting operation.

According to another aspect, a method for patterning a solar cell is provided. The method comprises providing a solar panel with a stack of layers including at least an absorber layer and a transparent conductive oxide (TCO) layer over the absorber layer and creating scribe lines in the solar panel by using a first nanosecond laser cutting operation that cuts through only a portion of a thickness of the stack and a second cutting step that cuts through a remaining thickness of the stack.

According to yet another aspect, a method for scribing a solar panel is provided. The method comprises: providing a thin film solar panel with a stack of layers having a thickness and including at least an absorber layer and a transparent conductive oxide (TCO) layer over the absorber layer; identifying scribe line regions of the solar cell; cutting through an upper portion of the stack of layers using a nanosecond laser cutting operation in the scribe line regions thereby leaving a lower portion of the stack of layers intact in the scribe line regions; and cutting through the lower portion of the stack of layers in the scribe line regions using one of a further nanosecond laser cutting operation and a mechanical cutting operation.

The preceding merely illustrates the principles of the disclosure. It will thus be appreciated that those of ordinary skill in the art will be able to devise various arrangements which, although not explicitly described or shown herein, embody the principles of the disclosure and are included within its spirit and scope. Furthermore, all examples and conditional language recited herein are principally intended expressly to be only for pedagogical purposes and to aid the reader in understanding the principles of the disclosure and the concepts contributed by the inventors to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the disclosure has been described in terms of exemplary embodiments, it is not limited thereto. Rather, the appended claims should be construed broadly, to include other variants and embodiments of the disclosure, which may be made by those of ordinary skill in the art without departing from the scope and range of equivalents of the disclosure.

1. A method for patterning a solar cell, said method comprising:
providing a solar panel with at least an absorber layer and a transparent conductive oxide (TCO) layer over said absorber layer; and
creating scribe lines in said solar panel using a multiple step process in which at least a first step of said multiple step process is a nanosecond laser cutting operation.

2. The method as in claim 1, wherein said absorber layer comprises copper indium gallium selenide (CIGS).

3. The method as in claim 1, wherein said solar cell further comprises a back electrode layer beneath said absorber layer, said back electrode layer formed of one of molybdenum and a further back electrode material, and wherein said creating scribe lines comprises removing said TCO layer and said absorber layer in scribe line regions.

4. The method as in claim 1, wherein said nanosecond laser operates using a pulse duration of about 0.1-100 nanoseconds.

5. The method as in claim 4, wherein said multiple step process of said creating comprises said first step of said nanosecond laser cutting operation and a second step comprising mechanical cutting.

6. The method as in claim 4, wherein said multiple step process of said creating comprises said first step and a second step comprising a further nanosecond laser cutting operation.

7. The method as in claim 6, wherein said first step comprises said nanosecond laser cutting through said TCO layer and said second step comprises said nanosecond laser cutting through said absorber layer.

8. The method as in claim 6, wherein said second step comprises said nanosecond laser cutting through said absorber layer and removing any residual material of said TCO layer and at least one of said first step and said second step includes said nanosecond laser cutting operation using a laser beam with UV, visible light, and IR radiation having a wavelength in the range of about 200-1100 nm.

9. The method as in claim 6, wherein a beam profile shape of said nanosecond laser is varied between said first step and said second step.

10. The method as in claim 1, wherein said first step removes a first width of material and a second step of said multiple steps removes a second width of material, said first width being greater than said second width.

11. The method as in claim 1, wherein said cutting produces a two-tiered scribe line profile including an upper portion having a first width and a lower portion having a second width, said first width being greater than said second width.

12. The method as in claim 11, wherein said second width lies within a range of about 50-100 microns and said first width is about 10-30 microns wider than said second width.

13. The method as in claim 1, wherein said nanosecond laser cutting operation includes a power within a range of about 3-20 uJoules.

14. The method as in claim 1, wherein said nanosecond laser cutting operation uses light radiation having a wavelength within a range of about 200 to 1100 nm.

15. A method for patterning a solar panel, said method comprising:
providing a solar panel with a stack of layers including at least an absorber layer and a transparent conductive oxide (TCO) layer over said absorber layer; and
creating scribe lines in said solar panel by using a first nanosecond laser cutting operation that cuts through only a portion of a thickness of said stack and a second cutting step that cuts through a remaining thickness of said stack.

16. The method as in claim 15, wherein said second cutting step comprises a mechanical cutting operation and wherein said creating scribe lines produces a two-tiered scribe line profile including an upper portion having a first width and a lower portion having a second width, said first width being greater than said second width.

17. The method as in claim 15, wherein said nanosecond laser cutting operation uses a laser with a pulse duration of about 0.8 to 30 nanoseconds.

18. A method for scribing a solar panel, said method comprising:
providing a thin film solar panel with a stack of layers having a thickness and including at least an absorber layer and a transparent conductive oxide (TCO) layer over said absorber layer;
identifying scribe line regions of said solar panel;
cutting through an upper portion of said stack of layers using a nanosecond laser cutting operation in said scribe line regions thereby leaving a lower portion of said stack of layers intact in said scribe line regions; and
cutting through said lower portion of said stack of layers in said scribe line regions using one of a further nanosecond laser cutting operation and a mechanical cutting operation.

19. The method as in claim 18, wherein said nanosecond laser cutting operation uses light radiation having a wavelength within the range of about 200-1100 nm, includes a power within a range of about 3-20 uJoules and operates using a pulse duration of about 0.1-100 nanoseconds, and wherein said cutting through said lower portion of said stack of layers in said scribe line regions comprises said mechanical cutting operation.

20. The method as in claim 18, wherein said absorber layer comprises copper indium gallium selenide (GIGS), and said cutting through said lower portion produces a two-tiered scribe line profile including an upper portion having a first width and a lower portion having a second width, said first width being greater than said second width.
